(19) United States
(12) Patent Application Publication
(10) Pub. No.: US 2009/0207539 A1
(43) Pub. Date: Aug. 20, 2009

(54) I/O CIRCUIT

(75) Inventor: Teruo SUZUKI, Kasugai-shi (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki-shi (JP)

(21) Appl. No.: 12/034,372

(22) Filed: Feb. 20, 2008

(51) Int. Cl. H02H 9/04; H03K 19/0175

(52) U.S. Cl. 361/56; 327/108

(57) ABSTRACT

The I/O circuit 1 is provided with a first NMOS driver 10 having a drain connected to a pad, a second NMOS driver 11 arranged in an active area which differs from the first NMOS driver 10 and having a drain connected to a source of the first NMOS driver 10 and a source connected to a ground potential, a level converter converting a level of an internal power source potential to a level of a power source potential, and a first NMOS transistor 26 having a drain connected to one output terminal of the level converter, a source connected to a ground potential, and a gate connected to another output of the level converter, and wherein the drain of the first NMOS transistor is connected to the gate of the second NMOS 11.

### CROSS-REFERENCE TO RELATED APPLICATIONS

This application is based upon and claims the benefit of priority from the prior Japanese Patent Application No. 2007-038959 filed on Feb. 20, 2007, the entire contents of which are incorporated herein by reference.

### BACKGROUND

1. Field

The present disclosure relates to an I/O circuit in which a driver circuit is separated from an ESD protection circuit.

2. Description of Related Art

According to a technology disclosed in James W. Miller, Michael G. Khazhinsky and James C. Weldon's “Engineering the Cascoded NMOS Output Buffer for Maximum Vt1”, 22nd EOS/ESD Symposium Proceedings, p. 308-317, 2000, it is known that if a first NMOS driver 10 and a second NMOS driver 11 that separate an active area are cascade-connected as shown in FIG. 5, an ESD breakdown voltage is improved.

Further, as shown in FIG. 6, research on the ESD voltage is carried out with respect to a driver circuit 201 in which a gate of a first NMOS driver 10 and a gate of a second NMOS driver 11 are both connected to a ground potential VSS, a driver circuit 202 in which a gate of a first NMOS driver 10 is connected to a ground potential VSS, and a gate of a second NMOS driver 11 is connected to an I/O pad, a driver circuit 203 in which a gate of a first NMOS driver 10 is connected to an I/O pad, and a gate of a second NMOS driver 11 is connected to a ground potential VSS, and a driver circuit 204 in which a gate of a first NMOS transistor 10 and a gate of a second NMOS driver 11 are both connected to an I/O pad.

FIG. 7 shows the results of the research on the ESD withstand voltage of the driver circuits 201 through 204. The arrival points in the graph showing the respective characteristics of the circuits indicate the ESD breakdown voltages and the breakdown currents for the circuits, respectively. While the driver circuit 202 and the driver circuit 204 break down at approximately 8.2V, the driver circuit 201 and the driver circuit 203 maintain a tolerance against ESD breakdown up to approximately 16V.

The common point between the driver circuit 201 and the driver circuit 203 is that the gate of the second NMOS driver 11 is connected to the ground potential VSS. Accordingly, it is clear that the ESD breakdown voltage is improved in the driver circuit having the cascade configuration shown in “Engineering the Cascoded NMOS Output Buffer for Maximum Vt1” by connecting the gate of the second NMOS driver 11 on the side where a source thereof is connected to the ground potential VSS, to the ground potential. FIG. 8 shows a conventional I/O circuit in which a capacitor 25 is provided between a gate terminal C of the second NMOS driver 11 and the ground potential, and the gate terminal C of the second NMOS driver 11 is held at the ground potential.

Additionally, another related technology is disclosed in the Published Japanese Translations of PCT International Patent Publication No. 2003-510827.

### SUMMARY

According to one aspect of an embodiment of the present invention, an I/O circuit is provided that comprises: a first NMOS driver having a drain connected to an I/O pad; a second NMOS driver laid out in an active area that differs from the first NMOS driver, the second NMOS driver having a drain connected to a source of the first NMOS driver and a source connected to a ground potential; a level converter having a latch configuration, the level converter being adapted to receive a first control signal and a signal complementary to the first control signal which are driven at an internal power source potential which is separated from a power source potential, and converting the first control signal and the signal complementary to the first control signal into a second control signal and a signal complementary to the second control signal which are in-phase with the first control signal and driven at the power source potential; and a first NMOS transistor having a drain connected to an output terminal of the level converter from which the second control signal is outputted, a source connected to a ground potential, and a gate connected to an output terminal of a signal complementary to the second control signal in the level converter; wherein the drain of the first NMOS transistor is connected to a gate of the second NMOS driver.

### BRIEF DESCRIPTION OF THE DRAWINGS

FIG. 1 is a circuit diagram showing a configuration of an I/O circuit according to the present embodiment;

FIG. 2 is a cross-section diagram showing a PMOSESD protective element in the case that an ESD test voltage is applied to an I/O pad;

FIG. 3 is a cross-section diagram showing a configuration of the ESD protective element;

FIG. 4 is a characteristic diagram showing an I-V characteristic of the ESD protective element;

FIG. 5 is a layout diagram showing a configuration of NMOS drivers in a cascade configuration;

FIG. 6 is a circuit diagram showing the connection in driver circuits having various configurations;

FIG. 7 is a characteristic diagram showing the ESD withstand voltage characteristics of the driver circuits having various configurations; and

FIG. 8 is a circuit diagram showing a configuration of a conventional I/O circuit.

### DETAILED DESCRIPTION OF THE PREFERRED EMBODIMENTS

Keeping the gate terminal C of the second NMOS driver 11 at the ground potential requires the use of a capacitor that has a large capacitance value. The use of the capacitor having a large capacitance value creates a problem that the layout surface is increased. If the signal level at the gate terminal transits from a ground potential to an “H” level when the second NMOS driver 11 is made conductive, the capacitor needs time to charge, which creates a problem that the transition time becomes long. Also, a problem occurs that the potential at the gate terminal C of the second NMOS driver 11 increases when the capacitor is used and is charged through a PMOS transistor 17.

It is provided an I/O circuit which comprises cascade-connected NMOS drivers, wherein the NMOS drivers on the ground side have a small area, the transition time to activate the NMOS drivers on the ground side is short, and the gate voltages of the NMOS drivers on the ground side are more reliably set to the ground potential.

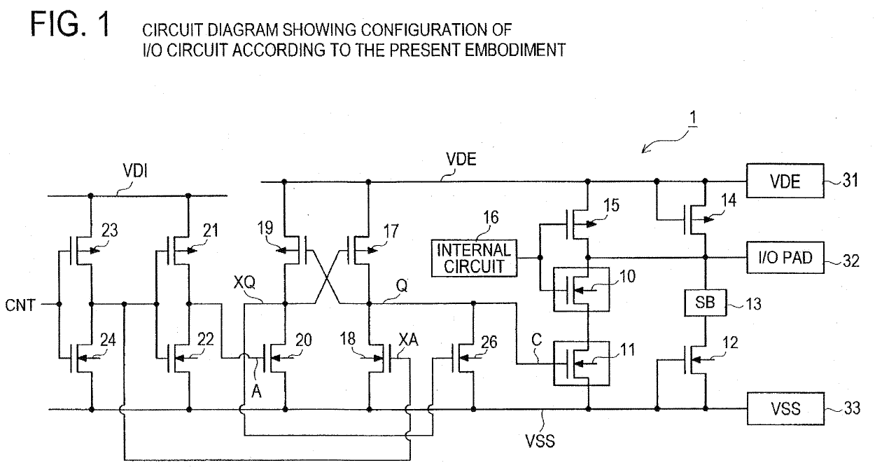

An embodiment of an I/O circuit will be described in detail hereinafter with reference to FIG. 1 through FIG. 4.

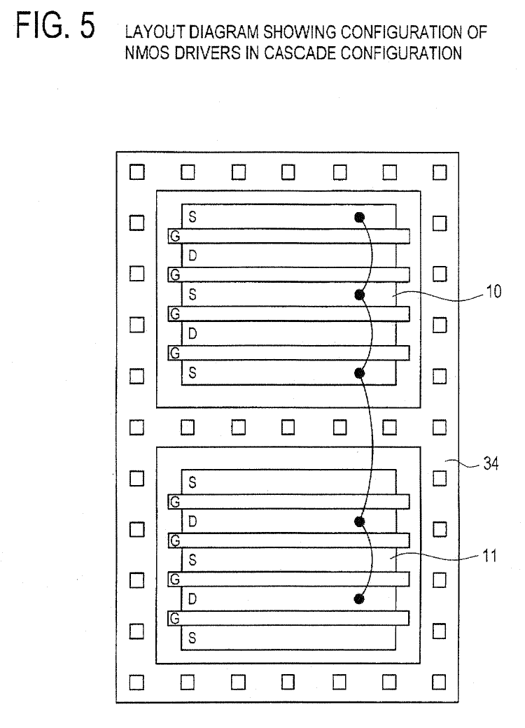

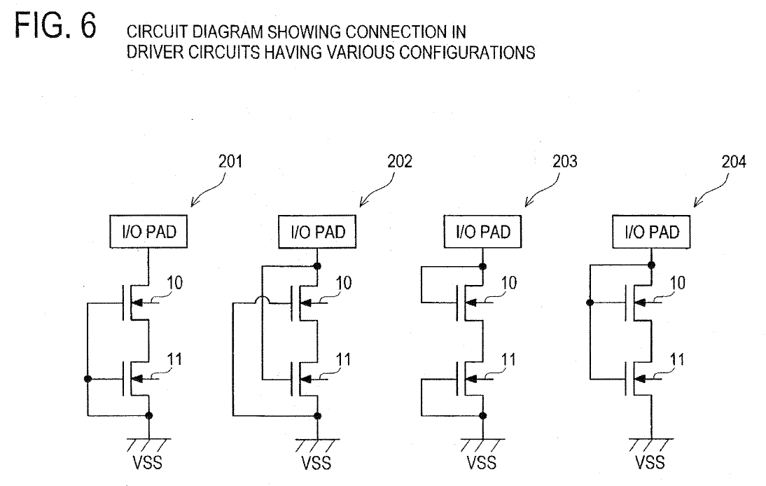

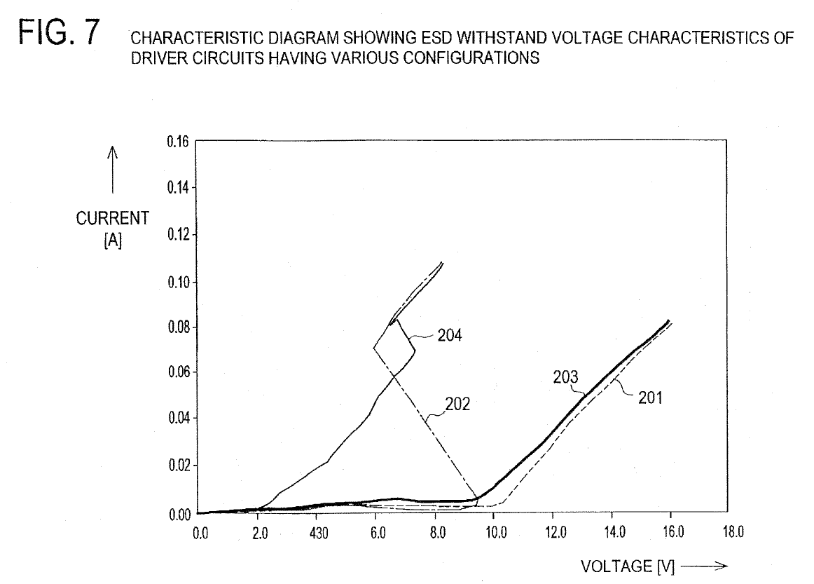

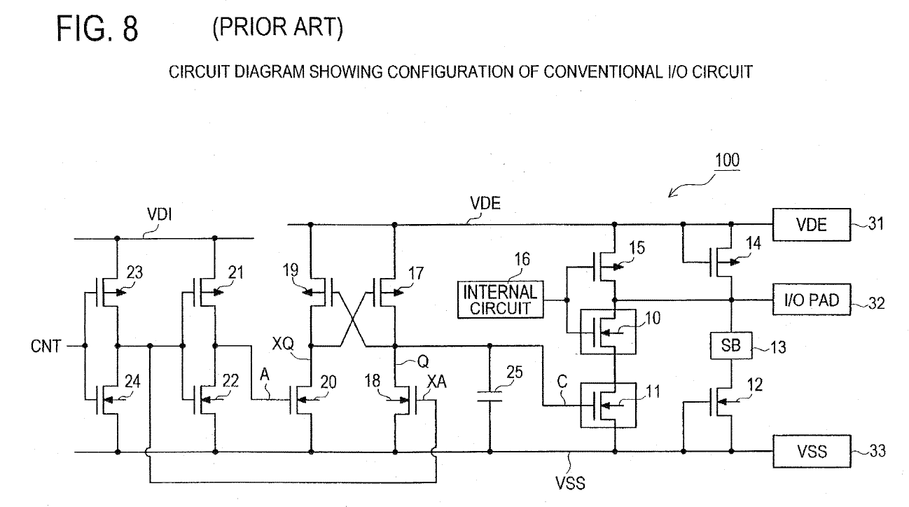

FIG. 1 is a circuit diagram showing a configuration of an I/O circuit 1 according to the present embodiment. The I/O circuit 1 is provided with a first NMOS driver 10 and a second NMOS driver 11. The first NMOS driver 10 and the second NMOS driver 11 are laid out so that an active area is divided between them as shown in FIG. 5. These drivers are surrounded at a periphery thereof by a guard ring 34 (a well tap of a back gate). A source of the first NMOS driver 10 and a drain of the second NMOS driver 11 are connected with each other in a wiring layer.

As described, the first NMOS driver 10 and the second NMOS driver 11 are each surrounded at a periphery thereof by a guard ring 34, which reduces electrical interference passing a bulk layer, thereby making it possible to further increase the ESD withstand voltage.

Returning to FIG. 1, the I/O circuit 1 is provided with an NMOS transistor 12 having a gate connected to the VSS and a silicide block 13 connected in series with the NMOS transistor 12, which serve as an ESD protective circuit. The I/O circuit 1 is also provided with a PMOS transistor 14 having a gate connected to an external power source VDE, and a PMOS transistor 15 that forms an inverter together with the first NMOS driver 10, which serve as an ESD protective circuit. The inverter constituted of the PMOS transistor 15 and the first NMOS driver 10 is driven by a signal outputted from an internal circuit 16.

Further, the I/O circuit 1 is also provided with a PMOS transistor 17 having a source connected to an external power source VDE and a gate connected to another inversion output terminal XQ, a NMOS transistor 18 having a source connected to the ground potential VSS, a drain connected to the drain of the PMOS transistor 17, and a gate serving as an inversion input terminal XA, a PMOS transistor 19 having a source connected to the external power source VDE and a gate connected to one output terminal Q, and a NMOS transistor 20 having a source connected to the ground potential VSS, a drain connected to the drain of the PMOS transistor 19, and a gate serving as an input terminal A. The PMOS transistor 17, NMOS transistor 18, PMOS transistor 19 and NMOS transistor 20 serve as a level converter adapted to convert a signal level of an internal power source VDI to a signal level of the external power source VDE. Also, the I/O circuit 1 comprises a NMOS transistor 26 having a gate connected to an inversion output terminal XQ, a drain connected to an output terminal Q and a source connected to the ground potential VSS. The output terminal Q of the level converter and the gate terminal C of the second NMOS driver 11 are connected.

The I/O circuit 1 is further provided with a PMOS transistor 21 and a NMOS transistor 22 constituting an inverter driven by the internal power source VDI, and a PMOS transistor 23 and a NMOS transistor 24 constituting an inverter driven by the internal power source VDI. The PMOS transistor 23 and the NMOS transistor 24 constituting the inverter receive a control signal CNT that controls the gate terminal C of the second NMOS driver 11.

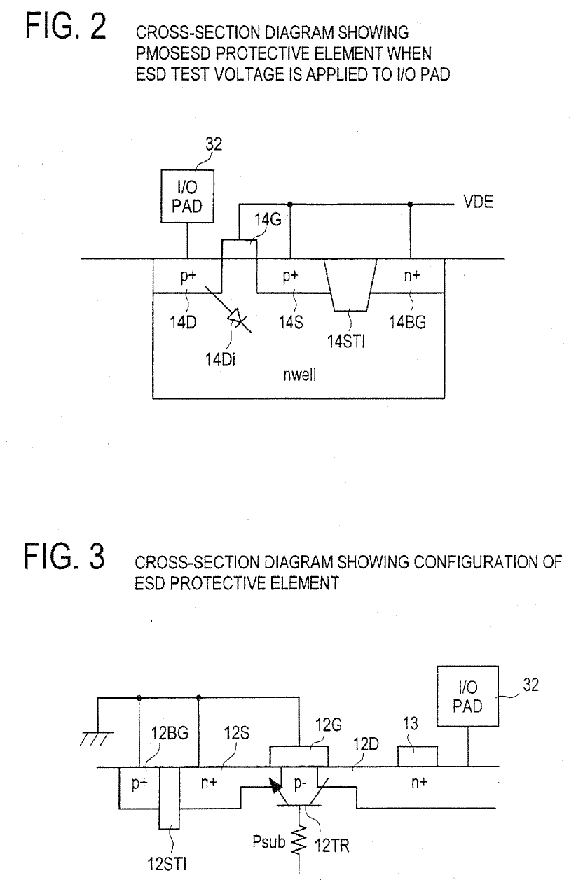

When the ESD is zapped to the I/O pad 32 with a positive polarity, with the VSS set as a base, a voltage is also applied to the external power source VDE from a parasitic diode 14Di, through a drain 14D of the PMOS transistor 14 and the I/O pad 32, and a back gate 14BG of the PMOS transistor 14 and the parasitic diode 14Di, as shown in FIG. 2.

The output of the inverter consisting of the PMOS transistor 21 and the NMOS transistor 22 and the output of the inverter consisting of the PMOS transistor 23 and the NMOS transistor 24 are in a state that a parasitic capacitance was discharged, and therefore, the outputs area ground potential.

Accordingly, the input terminal A and the inversion input terminal XA of the level converter both receive a ground potential. In the level converter, before voltage is applied for an ESD test, the output terminal Q and the inversion output terminal XQ are at a ground potential, however, when a voltage is applied for an ESD test, the PMOS transistor 17 and the PMOS transistor 19 become conductive and the potentials at the output terminal Q and the inversion output terminal XQ are raised. If the potential of the inversion output terminal XQ exceeds a threshold voltage of the NMOS transistor 26, the NMOS transistor 26 is made conductive. When the NMOS transistor 26 is made conductive, the signal level of the output terminal Q and the gate terminal C becomes a ground potential. As a result, the PMOS transistor 19 becomes completely conductive, and the level of the inversion output terminal XQ transits to an “H” level. As a result, the PMOS transistor 17 becomes non-conductive, and the inversion output terminal XQ is maintained at an “H” level, while the output terminal Q is maintained in a ground potential state (latching operation).

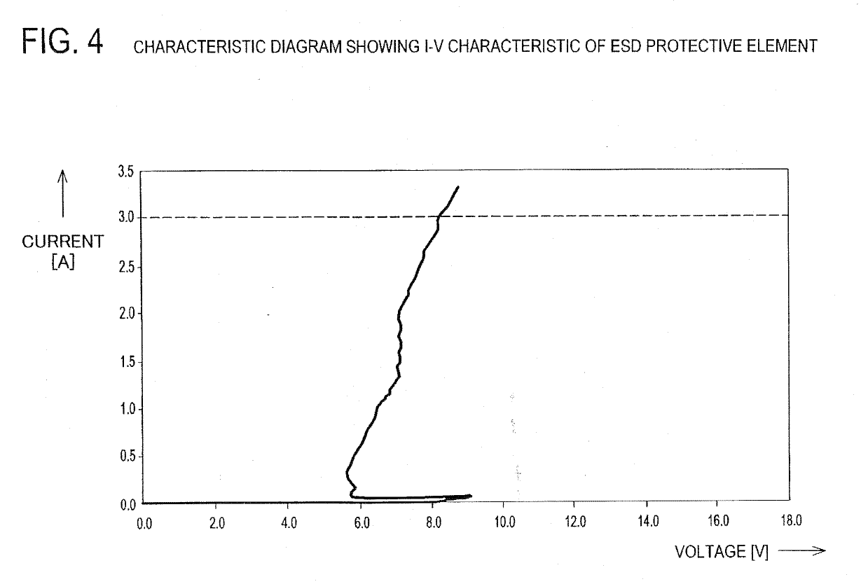

Next, a description will be given on the ESD protective circuit in which the silicide block 13 and the NMOS transistor 12 are connected in series from the I/O pad 32. FIG. 3 is a cross-section diagram showing a configuration of the ESD protective element. Since the drain 12D of the NMOS transistor 12 connected to the I/O pad 32 passes through the silicide block 13, the NMOS transistor 12 is connected with the I/O pad 32 by a bulk. The drain 12D (n+) of the NMOS transistor 12, the bulk (p−) of the NMOS transistor 12 and the source of the NMOS transistor 12 constitute a parasitic NPN transistor 12TR. The parasitic NPN transistor 12TR does not become conductive at a low voltage, however, it becomes conductive when the potential of the I/O pad 32 reaches approximately 9V due to a leak current, etc. In FIG. 4 which is a characteristic diagram showing an I-V characteristic of the ESD protective circuit, if the parasitic NPN transistor 12TR is made conductive once, the transistor snaps back and the voltage drops down to a hold voltage (approximately 6V), thereby allowing a large current which corresponds to the voltage to be subsequently flown. By comparison, pursuant to the standards for the ESD withstand voltage of the machine model, if a current of up to 3.0 A (shown by the broken line) can be flown, the withstand voltage can be expected to become equal to or above 200V.

In the I/O circuit 1 according to the present embodiment, since the gate terminal C of the second NMOS driver 11 is held at a ground potential by carrying out a latching operation, a driver circuit constituted by the first NMOS driver 10 and the second NMOS driver 11 has an ESD withstand voltage equal to or above approximately 9V, and the ESD withstand voltage can be maintained in the cascade-connected driver circuit constituted by the first NMOS driver 10 and the second NMOS driver 11, until the parasitic NPN transistor 12TR of the ESD protective circuit becomes conductive.

In the I/O circuit 1 of the present embodiment, the ground potential at the gate terminal C of the second NMOS driver is maintained without using a capacitor. Since a capacitor is not used, the entire layout surface of the I/O circuit 1 can be made more compact, as compared to the conventional circuit in which a capacitor is used.

Since the conventional I/O circuit 100 uses a large capacitance capacitor 25, the transit time from a ground potential to an “H” level is slow even in the case that the internal power source VDI is connected and the gate terminal C is always controlled. However, since the I/O circuit 1 of the present embodiment does not use a capacitor, the transit operation from a ground potential to an “H” level can be carried out rapidly.

In the conventional I/O circuit 100, a capacitor 25 is used to hold the gate terminal C at a ground potential. Thus, a problem occurs that the capacitor is charged through the PMOS transistor 17, which causes an increase in potential. Contrary to this, in the I/O circuit 1 of the present embodiment, the ground potential is maintained through the latch operation, which eliminates the risk of a raise in the potential of the gate terminal C.

The present disclosure is not limited to the above-described embodiment, and needless to say, various improvements and modifications thereof can be performed without departing from the scope of the disclosure.

For instance, although a description was given in the present embodiment of the case that the output of the first NMOS driver 10 having a one-stage configuration is an inverter, a plurality of drivers having the same configuration as the first NMOS driver 10 may be cascade-connected. For instance, if the output driver has a NAND configuration, a transistor having the same configuration as the first NMOS driver 10 may be one stage cascade-connected.

Although in the present embodiment the input terminal A and the inversion input terminal XA are controlled through the two inverters, one being constituted by the PMOS transistor 21 and the NMOS transistor 22, and the other one being constituted by the PMOS transistor 23 and the NMOS transistor 24, the PMOS transistor 21 and the NMOS transistor 22 may be removed so that the input terminal A maybe directly controlled by a control signal which is not shown.

The NMOS transistor 26 serves as one example of a first NMOS transistor, the NMOS transistor 12 serves as one example of a second NMOS transistor, the PMOS transistor 14 serves as one example of a first PMOS transistor, and the PMOS transistor 15 serves as one example of a second PMOS transistor Also, the PMOS transistor 17 serves as one example of a third PMOS transistor, the PMOS transistor 19 serves as one example of a fourth transistor, the NMOS transistor 18 serves as one example of a third NMOS transistor, and the NMOS transistor 20 serves as one example of a fourth NMOS transistor. Further, the PMOS transistor 21 and the NMOS transistor 22 serve as one example of a first inverter, and the PMOS transistor 23 and the NMOS transistor 24 serve as one example of a second inverter.

In the present embodiment, when ESD is applied to a pad, the output of a level converter is set to a midpoint potential. As a result, the first NMOS transistor is made conductive, and the gate of the second NMOS driver is set to a ground potential. Thus, it is possible to prevent breakdown caused by applying ESD to the pads of the first NMOS driver and the second NMOS driver.

According to the present disclosure, it is possible to provide an I/O circuit comprising cascade-connected NMOS drivers, wherein the NMOS drivers on the ground side have a small area, the transit time to an active state of the NMOS drivers on the ground side is short, and the gate voltages of the NMOS drivers on the ground side are reliably held at a ground potential.

What is claimed is:

1. An I/O circuit comprising:
a first NMOS driver having a drain connected to an I/O pad;
a second NMOS driver laid out in an active area that differs from the first NMOS driver, the second NMOS driver having a drain connected to a source of the first NMOS driver and a source connected to a ground potential;
a level converter having a latch configuration, the level converter being adapted to receive a first control signal and a signal complementary to the first control signal which are driven at an internal power source potential which is separated from a power source potential, and converting the first control signal and the signal complementary to the first control signal into a second control signal and a signal complementary to the second control signal which are in-phase with the first control signal and driven at the power source potential; and
a first NMOS transistor having a drain connected to an output terminal of the level converter from which the second control signal is outputted, a source connected to a ground potential, and a gate connected to an output terminal of a signal complementary to the second control signal in the level converter;
wherein the drain of the first NMOS transistor is connected to a gate of the second NMOS driver.

2. The I/O circuit according to claim 1, further comprising an ESD protection circuit arranged between the I/O pad and the ground potential.

3. The I/O circuit according to claim 2, wherein the ESD protection circuit is formed of a silicide block and a second NMOS transistor connected in series.

4. The I/O circuit according to claim 1, further comprising a first PMOS transistor having a drain connected to an I/O pad, and a source and gate connected to the power source potential.

5. The I/O circuit according to claim 1, further comprising:
a second PMOS transistor having a drain connected to the I/O pad, a source connected to the power source potential, and a gate connected to a gate of the first NMOS driver, and wherein the first NMOS driver is constituted by a NMOS transistor.

6. The I/O circuit according to claim 1, wherein a layout of the first NMOS driver and a layout of the second NMOS driver are both surrounded by a guard ring of a back gate.

7. The I/O circuit according to claim 1, wherein the level converter further comprises:
a third NMOS transistor having a drain connected to an output terminal of the second control signal, a source connected to a ground potential and a gate connected to an input terminal of a signal complementary to the first control signal in the first NMOS driver;
a fourth NMOS transistor having a drain connected to an output terminal of a signal complementary to the second control signal, a source connected to a ground potential, and a gate connected to an input terminal of the first control signal in the first NMOS driver;
a third PMOS transistor having a drain connected to an output terminal of the second control signal, a source connected to the power source potential, and a gate connected to an output terminal of a signal complementary to the second control signal; and
a fourth PMOS transistor having a drain connected to an output terminal of a signal complementary to the second control signal, a source connected to the power source potential, and a gate connected to an output terminal of the second control signal.

8. The I/O circuit according to claim 1, further comprising:
a first inverter driven at the internal power source potential, the first inverter having an output terminal connected to an input terminal of the first control signal in the level converter; and
a second inverter driven at the internal power source potential, the second inverter having an output terminal connected to an input terminal of a signal complementary to the first control signal in the level converter and an input terminal of the first inverter.
